(19) United States
(12) Patent Application Publication
(10) Pub. No.: US 2014/0091274 A1
(43) Pub. Date: Apr. 3, 2014

(54) MEMORY DEVICES HAVING UNIT CELL AS SINGLE DEVICE AND METHODS OF MANUFACTURING THE SAME

(71) Applicants: Young-bae KIM, Seoul (KR); Kyung-min KIM, Goyang-si (KR); In-gyu BAEK, Seoul (KR); Seong-jun PARK, Seoul (KR)

(72) Inventors: Young-bae KIM, Seoul (KR); Kyung-min KIM, Goyang-si (KR); In-gyu BAEK, Seoul (KR); Seong-jun PARK, Seoul (KR)

(21) Appl. No.: 13/941,835

(22) Filed: Jul. 15, 2013

(30) Foreign Application Priority Data
Sep. 28, 2012 (KR) 10-2012-0109282

(51) Int. Cl. H01L 45/00

(52) U.S. Cl. CPC H01L 45/145; H01L 45/1608; Y10S 977/734; Y10S 977/842; Y10S 977/943; B82Y 40/00
USPC 257/4; 438/382; 977/734; 977/842; 977/943

(57) ABSTRACT

In one embodiment, a memory device includes a first electrode layer on a substrate; a data storing layer on the first electrode layer; and a second electrode layer on the data storing layer. At least one of the first and second electrode layers may be formed of a material having a conduction band offset that varies with an applied voltage. One of the first and second electrode layers may be connected to a bit line and the other may be connected to a word line. The first electrode layer may include one of graphene and metastable oxide. The second electrode layer may include one of graphene and metastable oxide.

### CROSS-REFERENCE TO RELATED APPLICATION

This application claims priority under 35 U.S.C.§119 to Korean Patent Application No. 10-2012-0109282, filed on Sep. 28, 2012, in the Korean Intellectual Property Office, the disclosure of which is incorporated herein in its entirety by reference.

### BACKGROUND

1. Field

Some example embodiments relate to semiconductor devices, and/or more particularly, to memory devices having a unit cell as a single device and methods of manufacturing the same.

2. Description of the Related Art

When layers of a material having resistance variation characteristics are formed in an array, in order to read and/or write data to and/or from the layers, a large difference between a current corresponding to a voltage applied to a selected cell and a current corresponding to a voltage applied to unselected cells may be generated.

In order to generate such a large difference, a device called a selector may be used. A representative example of a selector is a transistor or a threshold switch.

However, in order to form such a device, a large number of processes may be needed and process compatibility has to be considered. Also, a transistor may use more space than a storage node. Accordingly, a selector such as a transistor may not be advantageous for high level memory integration.

### SUMMARY

Some example embodiments relate to memory devices that have high integration level and broad application range by including unit cells as single devices having a simplified structure.

Other example embodiments also relate methods of manufacturing memory devices.

Additional aspects will be set forth in part in the description which follows and, in part, will be apparent from the description, or may be learned by practice of example embodiments.

According to an example embodiment, a memory device includes a substrate; a first electrode layer and a second layer on the substrate; a data storing layer between the first electrode layer and the second electrode layer; a bit line connected to one of the first electrode and the second electrode layers; and a word line connected to the other of the first electrode and the second electrode layers. The second electrode layer may be over the first electrode layer. At least one of the first electrode and second electrode layers includes a material having a conduction band offset that varies in response to an applied voltage.

In the above memory device, the first electrode layer may be one of graphene and metastable oxide. Also, the second electrode layer may be one of graphene and metastable oxide.

The data storing layer may be a data storing layer of a non-volatile memory device. In this case, the non-volatile memory device may be, but not limited to, resistive random access memory (RRAM) or phase change random access memory (PRAM).

The data storing layer may be a data storing layer of embedded memory of a logic device.

The conduction band offset of the material of at least one of the first electrode layer and the second electrode layer may vary inversely proportional with the applied voltage to the first and second electrode layers.

A barrier layer may be between the data storing layer and the second electrode layer.

A first current may flow between the first electrode layer and the second electrode layer if the applied voltage is a program voltage applied to the word line. A second current may flow between the first electrode layer and the second electrode layer if the applied voltage is less than an absolute value of the program voltage and is applied to the word line. A magnitude of the first current may be greater than a magnitude of the second current.

The bit line may be one of a plurality of bit lines. The word line may be one of a plurality of word lines that intersect the plurality of bit lines. The first electrode layer, the data storing layer, and the second electrode layer may form a unit cell. The unit cell may be one of a plurality of unit cells disposed at intersections between the plurality of bit lines and the plurality of word lines respectively.

The substrate may be one of a semiconductor substrate and a semiconductor-on-insulator substrate.

According to another example embodiment, a method of manufacturing a memory device includes forming a first electrode layer on a substrate; forming a data storing layer on the first electrode layer; forming a second electrode layer on the data storing layer; and forming a bit line connected to one of the first electrode and second electrode layers, and a word line connected to the other of the first electrode and second electrode layers. At least one of the first electrode and second electrode layers includes a material having a conduction band offset that varies in response to an applied voltage.

In the above method, the applied voltage may vary inversely proportional with the conduction band offset of the first and second electrode layers.

The method may further include forming a barrier layer between the data storing layer and the second electrode layer.

In a memory device according to an example embodiment, a unit cell includes a single device. For example, although a unit cell conventionally includes a switching device and a storage connected thereto, if the memory device according to an example embodiment is a non-volatile memory device, a unit cell is formed of only a storage having a switching device function. Since the unit cell does not include a separate switching device, in comparison to a conventional case, an area of the unit cell may be greatly reduced and thus an integration level may be increased.

### BRIEF DESCRIPTION OF THE DRAWINGS

The foregoing and/or other aspects of example embodiments will become apparent and more readily appreciated from the following description of non-limiting embodiments, as illustrated in the accompanying drawings. The drawings are not necessarily to scale, emphasis instead being placed upon illustrating principles of example embodiments. In the drawings:

FIG. 1 is a plan view of an array of a memory device having a unit cell as a single device, according to an example embodiment;

FIG. 2 is a cross-sectional view along line 2-2′ of FIG. 1;

FIGS. 3 and 4 are cross-sectional views showing conduction bands of a first electrode layer, a data storing layer, a barrier layer, and a second electrode layer when a high voltage such as a driving voltage (program voltage) is applied thereto;

FIG. 5 is a cross-sectional view showing conduction bands of the first electrode layer, the data storing layer, the barrier layer, and the second electrode layer when a voltage lower than the driving voltage is applied thereto;

FIG. 6 is a graph showing non-linear voltage-current characteristics of a unit cell illustrated in FIG. 2;

FIGS. 7 through 9 are sequential cross-sectional views for describing a method of manufacturing a memory device, according to an example embodiment;

FIG. 10 is a block diagram of a memory device and control architecture according to an example embodiment;

FIG. 11 is a schematic view illustrating a card according to an example embodiment;

FIG. 12 is a schematic view of a system according to an example embodiment; and

FIGS. 13-14 are perspective views of memory device arrays according to some example embodiments.

### DETAILED DESCRIPTION

Example embodiments will now be described more fully with reference to the accompanying drawings, in which some example embodiments are shown. Example embodiments, may, however, be embodied in many different forms and should not be construed as being limited to the embodiments set forth herein; rather, these example embodiments are provided so that this disclosure will be thorough and complete, and will fully convey the scope of example embodiments of inventive concepts to those of ordinary skill in the art. In the drawings, the thicknesses of layers and regions are exaggerated for clarity. Like reference numerals in the drawings denote like elements, and thus their description may be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof. Expressions such as “at least one of,” when preceding a list of elements, modify the entire list of elements and do not modify the individual elements of the list.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

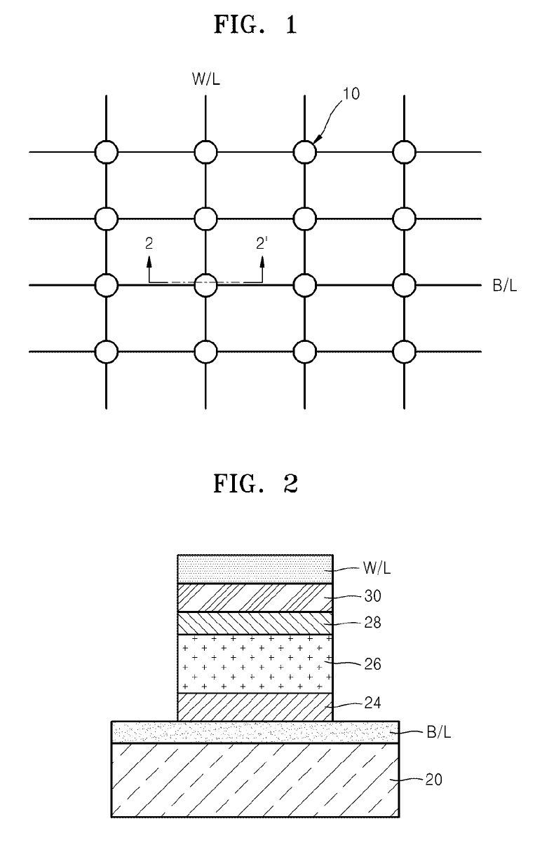

FIG. 1 is a plan view of an array of a memory device having a unit cell 10 as a single device, according to an example embodiment.

In FIG. 1, B/L denotes a bit line and W/L denotes a word line. A plurality of unit cells 10 are respectively located at the intersections of the word lines W/L and the bit lines B/L. The unit cell 10 includes a storage having a multi-function (hereinafter referred to as a multi-storage). The multi-storage may have multiple functions, for example, a data storing function and a switching device function.

Each of the word lines W/L is connected to one surface of the unit cell 10, and the corresponding one of the bit lines B/L may be connected to an opposite or other surface of the unit cell 10. A driving voltage or a program voltage is applied to a selected word line W/L, and a voltage lower than the program voltage, for example, a voltage corresponding to ½ of the program voltage, may be applied to unselected word lines W/L. As such, the program voltage may be applied to the unit cells 10 connected to the selected word line W/L. Also, a certain voltage is applied to a selected bit line B/L so as to select one of the unit cells 10 connected to the selected word line W/L, and thus, a read operation, a write operation, or an erase operation may be performed.

FIG. 2 is a cross-sectional view along line 2-2′ of FIG. 1. FIG. 2 shows the configuration of the unit cell 10.

Referring to FIG. 2, the bit line B/L is formed on a substrate 20. Since the bit line B/L is formed to be connected to a first electrode layer 24, the bit line B/L may be formed so the bit line B/L is not directly on the substrate 20. The substrate 20 may be of various types such as a semiconductor (e.g., silicon substrate) or a semiconductor-on-insulator (SOI) (e.g., silicon-on-insulator substrate). The substrate 20 may be a substrate for a memory device, a substrate for a cognitive device, or a substrate for an embedded memory of a semiconductor device; however example embodiments are not limited thereto. The first electrode layer 24 lies on the bit line B/L. The first electrode layer 24 may be formed of a material having a conduction band offset that varies with an applied voltage. The first electrode layer 24 may be formed of a material having bipolar characteristics. The above-described first electrode layer 24 may be formed of, for example, graphene or metastable transition metal oxide. The metastable transition metal oxide may be TaOx (x<2.5) or TiOx (x<2). In this case, the graphene may be formed as a monolayer or a multilayer. The graphene may have a thickness that is less than or equal to ten atomic carbon layers, less than or equal to four atomic carbon layers, or one atomic carbon layer. However, example embodiments are not limited thereto. The first electrode layer 24 may function as a lower electrode. A data storing layer 26 is formed on the first electrode layer 24. The data storing layer 26 may be formed of a material having a resistance that varies with an applied voltage. The data storing layer 26 may be a transition metal oxide or oxide including a transition metal. For example, the data storing layer may be ZrO₂, HfO₂, Ta₂O₅, TiO₂, NiO, SrTiO₃, or PCMO, but example embodiments are not limited thereto. Also, the data storing layer 26 may be a nitride including a transition metal, for example a transition metal nitride. The data storing layer 26 may be used in a storage node of non-volatile memory. For example, the data storing layer 26 may be a data storing layer of a storage node used in resistive random access memory (RRAM) or phase change random access memory (PRAM). Also, the data storing layer 26 may be a data storing layer of embedded memory of a logic device. Furthermore, the data storing layer 26 may be a data storing layer of a cognitive device. A barrier layer 28 lies on the data storing layer 26. The barrier layer 28 may be a material layer that may have a band gap of 2.0 eV or more. For example, the barrier layer 28 may be SiO, SiN, or AlO, but example embodiments are not limited thereto. A second electrode layer 30 lies on the barrier layer 28. According to the type of a storage node of memory, the barrier layer 28 may be omitted. The second electrode layer 30 may be formed of a material having a conduction band offset that varies with an applied voltage. The second electrode layer 30 may be formed of a material having bipolar characteristics. The above-described second electrode layer 30 may be formed of, for example, graphene or metastable transition metal oxide. The metastable transition metal oxide may be TaOx (x<2.5) or TiOx (x<2), and may have a thickness of 300 nm or less. In this case, the graphene may be formed as a monolayer or a multilayer. The graphene may have a thickness that is less than or equal to ten atomic carbon layers, less than or equal to four atomic carbon layers, or one atomic carbon layer. However, example embodiments are not limited thereto. The second electrode layer 30 may function as an upper electrode. The word line W/L is formed on the second electrode layer 30.

The first electrode layer 24 and the second electrode layer 30 may be formed of the same materials or different materials. Also, the first electrode layer 24 and the second electrode layer 30 may have about the same thickness or different thicknesses.

If a material for forming the data storing layer 26 has resistance variation characteristics like a data storing layer of RRAM, FIG. 2 may be an example of a unit cell of RRAM. If a material for forming the data storing layer 26 equals to the material for forming a data storing layer of PRAM, FIG. 2 may be an example of a unit cell of PRAM. This is because the first and second electrode layers 24 and 30 have conduction band offsets that greatly vary in order to achieve a switching function.

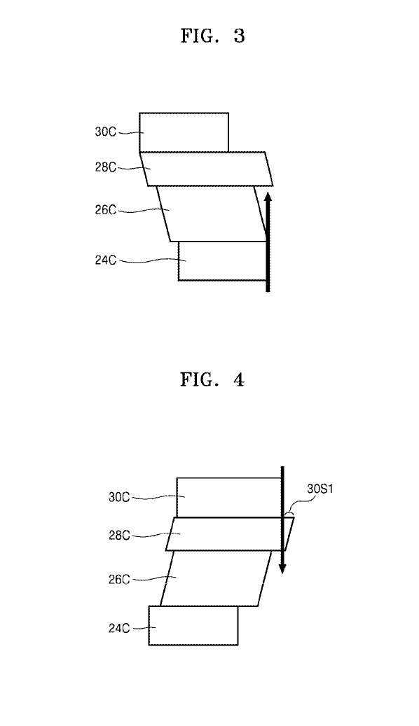

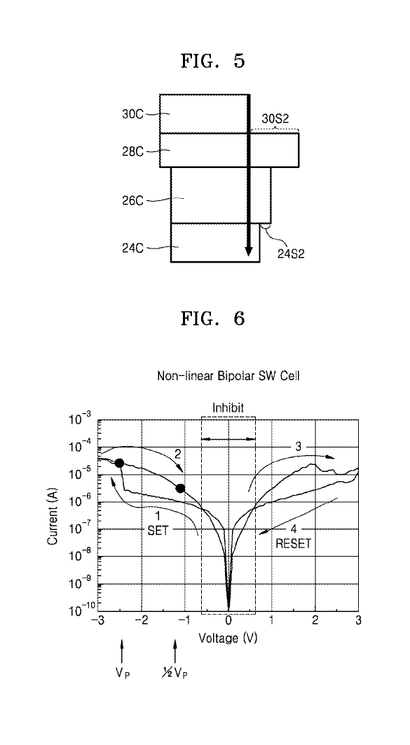

FIGS. 3 through 5 show conduction bands 24C, 26C, 28C, and 30C of the first electrode layer 24, the data storing layer 26, the barrier layer 28, and the second electrode layer 30. FIGS. 3 and 4 are cross-sectional views showing conduction bands of the above-mentioned layers when a high voltage such as a driving voltage (program voltage) is applied thereto. FIG. 5 is a cross-sectional view showing conduction bands of the above-mentioned layers when a voltage lower than the driving voltage, for example, almost 0V, is applied thereto. FIG. 3 shows a result when the driving voltage is a positive voltage, and FIG. 4 shows a result when the driving voltage is a negative voltage.

When the first and second electrode layers 24 and 30 are formed of graphene, if a high voltage is applied as illustrated in FIGS. 3 and 4, offsets of the conduction bands 24C and 30C of the first and second electrode layers 24 and 30 may be small. A conduction band offset is illustrated by reference number 30S1 in FIG. 4. If a low voltage is applied as illustrated in FIG. 5, the offsets of the conduction bands 24C and 30C of the first and second electrode layers 24 and 30 may be increased. Such a phenomenon may also occur when metastable oxide is used to form the first and second electrode layers 24 and 30 and, in this case, the offsets of the conduction bands 24C and 30C may be reduced or increased due to moving of oxygen atoms according to an applied voltage. Conduction band offsets 24S2 and 30S2 are illustrated in FIG. 5.

As such, a current flowing through a unit cell is increased if a voltage applied to the unit cell is a high voltage such as a driving voltage, and is reduced if the voltage applied to the unit cell is low. According to the above characteristics, in FIG. 1, only the selected unit cell 10 may be driven by applying a driving voltage only to the selected unit cell 10 and applying a voltage lower than the driving voltage to the other unit cells 10.

As described above, if the first and second electrode layers 24 and 30 are formed of a material having a conduction band offset that varies with an applied voltage, the unit cell 10 may be selected and driven without forming an additional switching device such as a transistor in the unit cell 10. As such, an area of the unit cell 10 may be reduced, a larger number of unit cells 10 may be formed within a limited region, and thus, an integration level of a memory device may be increased.

FIG. 6 is a graph showing non-linear voltage-current characteristics of the unit cell 10 illustrated in FIG. 2.

Referring to FIG. 6, a current is increased when a program voltage (driving voltage) Vp is applied to the unit cell 10, and a current is reduced if the applied program voltage Vp is reduced to half of the program voltage Vp (½ Vp). In other words, a first current may flow between the first electrode layer 24 and the second electrode layer 30 of the unit cell 10 shown in FIG. 2 when the applied voltage is a program voltage Vp and is applied to the word line W/L, and a second current may flow between the first electrode layer 24 and the second electrode layer 30 of the unit cell 10 shown in FIG. 2 when the applied voltage is less than an absolute value of the program voltage Vp (e.g., the applied voltage may be reduced to ½ Vp) and is applied to the word line W/L, and a magnitude of the first current may be greater than a magnitude of the second current.

If a current flowing when the program voltage Vp is applied to the unit cell 10 is referred to as Ip and a current flowing when half of the program voltage Vp is applied to the unit cell 10 is referred to as I(½ Vp), Ip/I(½ Vp) refers to an inhibiting ratio. If the inhibiting ratio is increased, a data write operation margin and a read operation margin may be increased, and thus, malfunctions during data write and read operations may be reduced.

Data may be recorded by applying the program voltage Vp to the unit cell 10, and the recorded data may be read by applying a read voltage between Vp and ½ Vp to the unit cell 10. First data is recorded if a current measured when the read voltage is applied to the unit cell 10 is greater than a reference current, or if a measured resistance is less than a reference value. Second data is recorded if the current measured when the read voltage is applied is less than the reference current, or if the measured resistance is greater than the reference value. One of the first and second data may be ‘1’ and the other may be ‘0’.

If a sufficient operation margin is ensured even when a voltage between Vp and ½ Vp is divided into a plurality of periods, multiple bits may be recorded and read. In FIG. 6, a negative voltage region may correspond to a set voltage and a positive voltage region may correspond to a reset voltage. Thus, data recorded on the data storing layer 26 may be erased by applying a positive voltage or a negative voltage to the unit cell 10 according to the polarity of a driving voltage. In FIG. 6, reference numerals 1 to 4 indicate a voltage sweeping order.

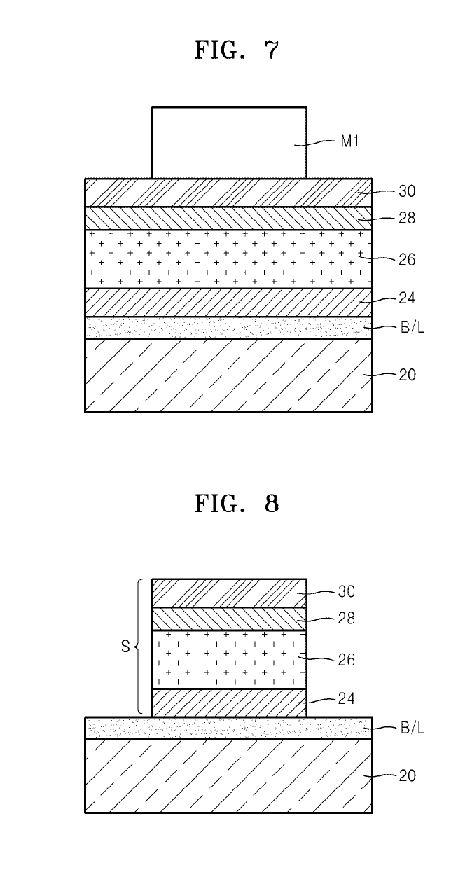

A method of manufacturing a memory device, according to an example embodiment, will now be described with reference to FIGS. 7 through 9.

In relation to the above-described elements, the same reference numerals are used and repeated descriptions thereof are not provided.

Initially, referring to FIG. 7, the bit line B/L is formed on the substrate 20. The first electrode layer 24 is formed on the bit line B/L. The data storing layer 26, the barrier layer 28, and the second electrode layer 30 are sequentially formed on the first electrode layer 24. A mask M1 for defining a partial region of the second electrode layer 30 is formed on the second electrode layer 30. The mask M1 defines a region for forming the unit cell 10 on the substrate 20. The mask M1 may be, for example, a photoresist pattern. Then, the second electrode layer 30 around the mask M1 is etched, and the barrier layer 28, the data storing layer 26, and the first electrode layer 24 under the etched second electrode layer 30 are also sequentially etched. After that, the mask M1 is removed. As a result, a stack S1 including the first electrode layer 24, the data storing layer 26, the barrier layer 28, and the second electrode layer 30 sequentially stacked on the bit line B/L is formed.

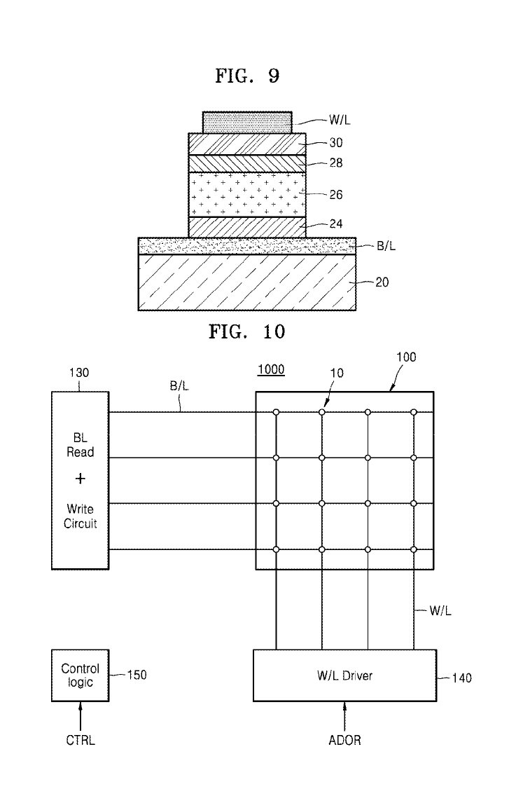

Then, as illustrated in FIG. 9, the word line W/L is formed on an upper surface of the stack S1. As such, a unit cell of memory which does not includes a switching device and includes only a storage node is formed.

FIG. 10 is a block diagram of a memory device according to an example embodiment.

Referring to FIG. 10, a memory device 100 having an array of unit cells 10 may be connected to a read and write circuit 130 through a plurality of bit lines B/L. The memory device 100 may be connected to a driver circuit 140 through a plurality of word lines W/L. Each one of the bit lines B/L may connect unit cells 10 in a common row of the memory device 100. Each one of the word lines W/L may connect unit cells 10 in a common column of the memory device 100.

A control logic 150 may control read, write, and erase operations of the memory device 100 by utilizing the read and write circuit 130 and the driver circuit 140. An external controller (not shown) may direct control commands CTRL that instruct the control logic 150 to perform read, write, and/or erase operations. The control logic 150 may direct the bit line read and write circuit 130 to apply a certain voltage to a selected bit line BL during a read or erase operation. The control logic 150 may direct the driver circuit 140 to apply a negative or positive program voltage Vp to a selected word line WL (depending on a SET or RESET operation as described above with regard to FIG. 6) and half of the program voltage to an unselected word line WL. The driver circuit 140 may receive an address signal ADDR from the control logic 150 that instructs the driver circuit 140. Based on the address signal ADDR, the driver circuit 140 may select a word line W/L corresponding to a unit cell 10 desired for a read, write, and/or erase operation.

While FIG. 10 illustrates one example of a memory device 1000 including a control architecture with a control logic 150, read and write circuit 130, and a driver circuit 140, example embodiments are not limited thereto. One having ordinary skill would appreciate the control architecture and method of operating a memory device 100 may be modified in various forms.

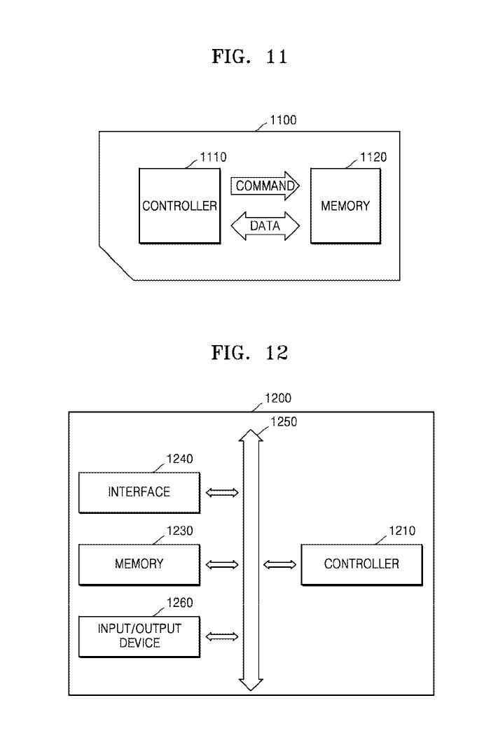

FIG. 11 is a schematic view illustrating a card according to an example embodiment.

Referring to FIG. 11, a card 1100 according to an example embodiment may include a controller 1110 and a memory device 1120. The controller 1110 and memory device 1120 may be arranged to for the controller 1110 to control read, write, and/or erase operations of the memory device 1120. Additionally, the controller 1110 and memory device 1120 may be arranged to exchange data. The memory device 1120 may include one or more of the foregoing and subsequently-described memory devices according to example embodiments.

FIG. 12 is a schematic view of a system according to an example embodiment.

Referring to FIG. 12, the system 1200 may include a controller 1210, an input/output device 1260, a memory 1230, and an interface 1240, all of which may communicate with each other through a bus 1250. The memory 1230 may include one or more of the foregoing and subsequently-described memory devices according to example embodiments. The interface 1240 may be a data transmission path between the system 1200 and other external devices. The input/output device 1260 may be, for example, a keypad, a keyboard, or a display device. The controller 1210 may be configured to control read, write, and/or erase operations of the memory 1230 and to control communication between the interface 1240, memory 1230, and input/output device 1260. The controller 1210 may be a microprocessor, a digital signal processor, a microcontroller; however, example embodiments are not limited thereto.

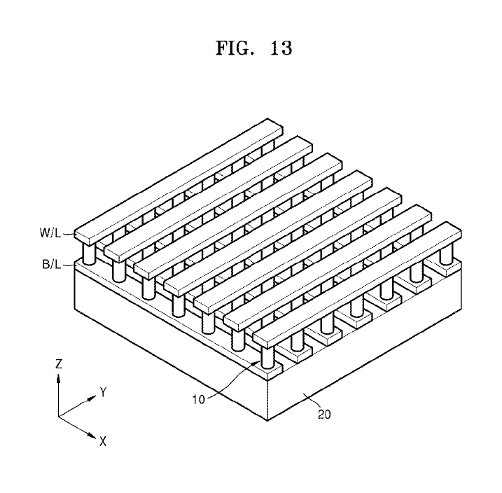

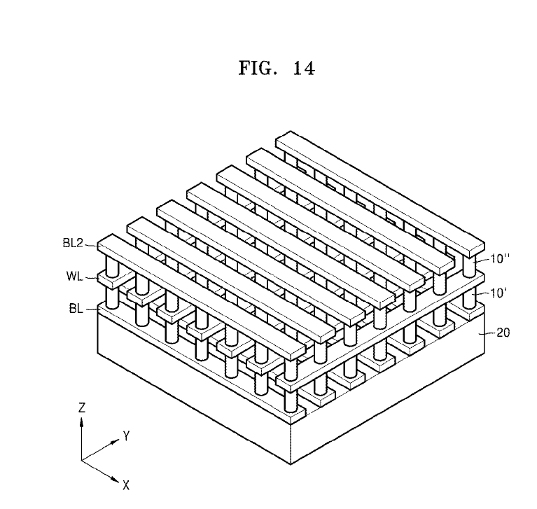

FIGS. 13-14 are perspective views of memory device arrays according to some example embodiments.

Referring to FIG. 13, the memory device illustrated in FIG. 1 may be arranged as a cross-point array where a plurality of unit cells 10 are disposed at intersections between a plurality of bit lines B/L and a plurality of word lines W/L on a substrate 20.

Referring to FIG. 14, a memory device array according to an example embodiment may include a plurality of unit cell arrays stacked on each other. For example, a plurality of unit cells 10′ may be arranged at the intersections between a plurality of bit lines BL and a plurality of word lines WL on a substrate 20. Additionally, another plurality of unit cells 10″ may be arranged at the intersection between the plurality of word lines WL and a plurality of second bit lines BL2. The unit cells 10′ and 10″ may be the same as (and/or substantially the same as) the unit cell 10 shown in FIG. 1.

It should be understood that example embodiments described herein should be considered in a descriptive sense only and not for purposes of limitation. Descriptions of features or aspects within each device and/or method according to example embodiments should typically be considered as available for other similar features or aspects in other devices and/or methods according to other example embodiments.

While some example embodiments have been particularly shown and described, it will be understood by one of ordinary skill in the art that variations in form and detail may be made therein without departing from the spirit and scope of the claims.

What is claimed is:

1. A memory device comprising:
a substrate;
a first electrode layer and a second electrode layer on the substrate,
the second electrode layer being over the first electrode layer,
at least one of the first electrode layer and the second electrode layer including a material having a conduction band offset that varies in response to an applied voltage;
a data storing layer between the first electrode layer and the second electrode layer;
a bit line connected to one of the first electrode and the second electrode layers; and
a word line connected to the other of the first electrode and the second electrode layers.

2. The memory device of claim 1, wherein the first electrode layer includes one of graphene and a metastable oxide.

3. (canceled)

4. The memory device of claim 1, wherein the second electrode layer includes one of graphene and a metastable oxide.

5. The memory device of claim 1, wherein the data storing layer is a data storing layer of a non-volatile memory device.

6. (canceled)

7. The memory device of claim 1, wherein the data storing layer is a data storing layer of embedded memory of a logic device.

8. The memory device of claim 1, wherein the conduction band offset of the material of at least one of the first electrode layer and the second electrode layer varies inversely proportional to the applied voltage.

9. The memory device of claim 1, further comprising:
a barrier layer between the data storing layer and the second electrode layer.

10. The memory device of claim 1, wherein
a first current flows between the first electrode layer and the second electrode layer if the applied voltage is a program voltage applied to the word line;
a second current flows between the first electrode layer and the second electrode layer if the applied voltage is less than an absolute value of the program voltage and is applied to the word line; and
a magnitude of the first current is greater than a magnitude of the second current.

11. The memory device of claim 1, wherein the bit line is one of a plurality of bit lines,
the word line is one of a plurality of word lines that intersect the plurality of bit lines,
the first electrode layer, the data storing layer, and the second electrode layer form a unit cell, and
the unit cell is one of a plurality of unit cells disposed at intersections between the plurality of bit lines and the plurality of word lines respectively.

12. The memory device of claim 1, wherein the substrate is one of a semiconductor substrate and a semiconductor-on-insulator substrate.

13. A method of manufacturing a memory device, the method comprising:
forming a first electrode layer on a substrate;
forming a data storing layer on the first electrode layer;
forming a second electrode layer on the data storing layer,
at least one of the first electrode layer and the second electrode layer including a material having a conduction band offset that varies in response to an applied voltage; and
forming a bit line connected to one of the first electrode and the second electrode layers; and
forming a word line connected to the other of the first electrode and the second electrode layers.

14. The method of claim 13, wherein the first electrode layer includes one of graphene and metastable oxide.

15. (canceled)

16. The method of claim 13, wherein the second electrode layer includes one of graphene and metastable oxide.

17. The method of claim 13, wherein the data storing layer is a data storing layer of a non-volatile memory device.

18. (canceled)

19. The method of claim 13, wherein the data storing layer is a data storing layer of embedded memory of a logic device.

20. The method of claim 13, wherein the conduction band offset of the material of at least one of the first electrode layer and the second electrode layer varies inversely proportional with the applied voltage.

21. The method of claim 13, further comprising:
forming a barrier layer between the data storing layer and the second electrode layer.

22. The method of claim 13, wherein a first current flows between the first electrode layer and the second electrode layer if the applied voltage is a program voltage applied to the word line;
a second current flows between the first electrode layer and the second electrode layer if the applied voltage is less than an absolute value of the program voltage and is applied to the word line; and
a magnitude of the first current is greater than a magnitude of the second current.

23. The method of claim 13,
the forming a bit line includes forming a plurality of bit lines,
the forming a word line includes forming a plurality of word lines that intersect the plurality of bit lines,
the forming the first electrode layer includes forming a plurality of first electrodes on the substrate,
the forming the data storing layer includes forming a plurality of data storing structures on the plurality of first electrodes,
the forming the second electrode layer includes forming a plurality of second electrodes on the plurality of data storing structures,
the plurality of first electrodes, the plurality of data storing layers, and the plurality of second electrodes respectively define a plurality of unit cells disposed at intersections between the plurality of bit lines and the plurality of word lines.

24. The method of claim 13, wherein the substrate is one of a semiconductor substrate and a semiconductor-on-insulator substrate.
